(19) United States
(12) Patent Application Publication
(10) Pub. No.: US 2009/0040418 A1
(43) Pub. Date: Feb. 12, 2009

(54) LED device and back panel of liquid crystal display

(75) Inventors: Shin-Ming Kao, Taoyuan County (TW); Yu-Cheng Lin, Taoyuan County (TW); Jaw-Shin Cheng, Taipei (TW)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DUPONT DE NEMOURS AND COMPANY, WILMINGTON, DE (US)

(21) Appl. No.: 11/891,347

(22) Filed: Aug. 10, 2007

(51) Int. Cl. H01L 29/22; G02F 1/1335; H01L 21/02

(52) U.S. Cl. 349/61; 257/94; 438/26; 257/E33.057; 257/E33.048

(57) ABSTRACT

A LED device of the present invention includes a substrate comprising a Cu and/or Al; a diamond-like carbon layer disposed on the substrate; an electric circuit formed on the diamond-like carbon layer; and a LED chip electrically connected to the electric circuit. The LED can be used as a light source of back light of liquid crystal display.

### BACKGROUND OF THE INVENTION

1. Field of the Invention

The present invention relates to a light emitting diode (LED). The LED of the present invention can be used for the back panel of liquid crystal display (LCD).

2. Technical Background

LED is expected as a light source of the next generation. The possible application of LED includes illumination, back light of liquid crystal display, display of instrumental panel of automobile, optical disk, etc.

When LED are used in an electric device, it is necessary to solve the problem caused by heat. The temperature of LED chips can significantly increase when supplied with a large amount of power.

In the case where a large amount of power is supplied to a presumably small mounting region for a light source, there is a risk that the LED chip may store heat and the temperature may increase. In addition, even in the case where this heat is conveyed to the thermal conductive substrate on which the LED chip is mounted, this substrate stores heat, which increases the temperature, and thereby, there is a risk that the temperature of the LED chip may also increase.

It is necessary to appropriately release heat generated in an LED chip to the outside so as to prevent the temperature of the LED chip from excessively increasing, in order to make an LED illumination device emit a large amount of light efficiently.

U.S. patent application publication (2005-276052) discloses illumination systems wherein diamond-like carbon (DLC) is disposed for the purpose of heat diffusion on the surface of ceramic such as AlN, GaN or SiC.

Various requirements, however, still exist for a LED device, especially in the case that a LED device is used in a display application, such as the back light of LCD. These requirements include: (1) more thermal conductivity (2) decrease of production cost, and (3) applicability for larger size.

### SUMMARY OF THE INVENTION

An object of the invention is to provide a LED device, wherein the substrate of the LED device has high thermal conductivity, the LED device can be produced economically, and the LED device with large area can be easily produced.

One embodiment of the present invention is a LED device, comprising a substrate comprising a Cu and/or Al; a diamond-like carbon layer disposed on the substrate; an electric circuit formed on the diamond-like carbon layer; and a LED chip mounted on the substrate and electrically connected to the electric circuit.

Another embodiment of the present invention is a back panel of liquid crystal display, wherein the LED devices is used as a source of light.

The present invention further provides a method of forming a LED device comprising: providing a substrate comprising a Cu and/or Al; providing a diamond-like carbon layer disposed on the substrate; forming an electric circuit formed on the diamond-like carbon layer; and electrically connecting a LED chip to the electric circuit.

A substrate made of metal or alloy such as Copper or Aluminum or alloy thereof can be easily produced in low cost. Further, such metal or alloy material has a high thermal conductivity as compared with ceramics. Furthermore, large LED panels can be easily manufactured by using metal or alloy substrate. This effect is very beneficial in terms of display application such as liquid crystal display (LCD), the panel size of which has been continuously increasing.

Additionally, a diamond-like carbon is disposed on the surface of the substrate, resulting in higher thermal conductivity due to the effective heat dissipation and conduction by the DLC.

### BRIEF DESCRIPTION OF THE DRAWINGS

FIG. 1 is one embodiment of the LED device of the present invention.

FIG. 2 is another embodiment of the LED device of the present invention.

FIG. 3 is still another embodiment of the LED device of the present invention.

### DETAILED DESCRIPTION OF THE INVENTION

The present invention has the advantage of high thermal conductivity, lower cost, and easiness of handling and the ability to be mass produced for large areas by using Al and/or Cu as a substrate and diamond-like carbon (DLC) as a interlayer between the substrate and electric circuit connected to a LED chip.

The thermal conductivity of GaN, AlN and SiC are 130 W/m-K, 170-230 W/m-K and 120 W/m-K respectively while the thermal conductivity of Al and Cu are 150-230 W/m-K and 400 W/m-K respectively. By using a metal or alloy with high thermal conductivity, thermal management performance of LED device can be strengthened.

In general, a production cost for metal or alloy plate is not expensive. This means a lower material cost, resulting in lower device cost for LED device. Because of the mechanical strength of metals and alloys (toughness, not as brittle as ceramics), it's much easier to process metal or alloy substrate such as cutting, hence lower manufacturing cost can be achieved. Also, it is much easier to manufacture metal or alloy substrate in larger scale, where the panel size of ceramics are typically limited to 4.5 inch sq.

The LED device of the present invention can be manufactured, for example, by providing a substrate comprising Cu and/or Al; forming a DCL layer on the substrate; forming an electric circuit on the DLC layer; forming an electric circuit on the DLC layer; and mounting a LED chip thereon and electrically connecting the LED chip to the electric circuit.

1. Substrate

The substrate of the present invention comprises Cu and/or Al. The substrate can be a Al plate, a Cu plate, a Al-containing alloy plate or a Cu-containing alloy plate. The conductive substrate can be used in the present invention. In the case that the substrate contains Al, the surface in the direction of the DLC layer is preferably anodized by oxygen.

The Al-containing alloy includes, but not limited to, Al—Cu, Al—Mn, Al—Si, Al—Mg, Al—Mg—Si, Al—Zn—Mg and Al—Zn—Mg—Cu. The Cu-containing alloy includes, but not limited to, Cu—Ni, Cu—Ni—Si, Cu—Sn, Cu—Cr—Zr—Zn, Cu—Fe—P, Cu—Ni—Sn—P, Cu—Mo, Cu—Co, Cu—Fe, Cu—Cr, Cu—Mo—Ni, Cu—Mo—Cr, Cu—Mo—Co, and Cu—Mo—Fe.

2. DLC layer Various types of DLC can be used in the present invention. The DLC with high thermal conductivity is preferably used in terms of efficient heat diffusion. As a method of producing DLC, JP H10-072285, JP2002-115080, US2005-0260411 may be referred. However, other references can be referred instead of or in addition to these references.

The DLC layer may be formed with a chemical vapor deposition (CVD) process. In the CVD process, precursor molecules in a gas phase may be dissociated, or activated, by an energy source to form active species, such as reactive radicals, ions, or atoms.

The CVD process may occur at atmospheric pressure (about 760 Torr) or higher with an energy source that may include a combustion flame source, such as an oxyacetylene torch source or a plasma torch source. The plasma torch source may include a Direct Current (DC) plasma arc jet source.

The CVD process may occur at atmospheric pressure (about 760 Torr) or lower with an energy source that may include a thermal source, such as a hot filament (HF) source. The HF source may include a single filament or multiple filaments.

The CVD process may occur at atmospheric pressure (about 760 Torr) or lower with an energy source that may include an electron or ion bombardment source, such as an electrical discharge source or a plasma source.

The DLC layer may be formed by other method. For example, the DLC layer can be formed by a physical vapor deposition (PVD) process. The condition of the PVD is preferred to be determined based on the desired thickness and physical property of DCL layer.

3. Electric circuit

Electric circuit can be formed with a conductive metal such as Ag, Cu, Al, etc. Ag is a preferable conductive metal constituting the electric circuit in terms of solder leach resistance. The electric circuit can be formed in various ways. The way of forming the electric circuit is not limited in the present invention. Such way includes the application of thick film paste, the transfer of conductive tape, and the electroplating on the preformed base conductive pattern. The thick film paste is cured or fired after the paste is applied. For example, the thick film paste is cured at the temperature of less than 300° C. Alternatively, the thick film paste is fired at the temperature of more than 300° C.

Commercially available thick film paste can be used in the present invention. For example, such thick film paste can be obtained from E. I. du Pont de Nemours and Company.

The examples of the electroplating include, for example, autocatalytic electroless plating and direct copper plating.

4. LED Chip

LED chip is mounted on the aforementioned layer. There are several pattern of mounting.

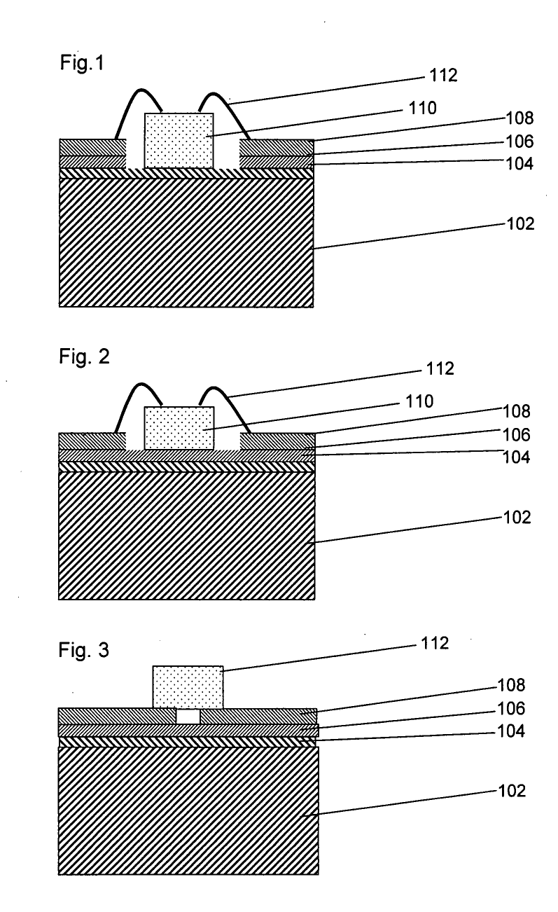

FIG. 1 shows one embodiment of the present invention. The LED device at FIG. 1 includes a substrate 102, anodized layer 104 formed on the surface of the substrate 102, a DLC layer 106 disposed on the anodized layer 104; an electric circuit 108 formed on the DLC layer 106; a LED chip 110 mounted on the anodized layer 104, and a wire bond 112 electrically connecting the LED chip 110 with the electric circuit 108. In this embodiment, the LED chip 110 is mounted on the surface of the anodized layer 104. In the case that the anodized layer 104 is not formed, the LED chip is mounted on the surface of the substrate 102.

FIG. 2 shows another embodiment of the present invention. In the LED device at FIG. 2, the LED chip 110 is mounted on the surface of the DLC layer 106.

When the LED chip 110 is mounted on the surface of the DLC layer 106, the heat from LED chip 110 can be efficiently diffused into the DLC layer 106, which has high thermal conductivity.

FIG. 3 shows still another embodiment of the present invention. In this embodiment, the LED chip 110 is flip-chip bonded and connected with the electric circuit 108 without using the wire bond. Conductive adhesive or solder can be used to attach the LED chip 110 to the electric circuit 108. The conductive adhesive includes, but not limited to, a conductive paste including Ag particle, epoxy resin is cited.

As for ways of bonding the LED chip to the substrate, eutectic die-attach, polymer-based adhesive or solder can be used.

### EXAMPLES

The present invention will be described in further detail by giving practical examples. The scope of the invention, however, is not limited in any way by these practical examples.

In order to investigate the performance of the present invention, the following experiments were carried out.

1. Solder leach resistance of the electrically conductive circuit Solder leach resistance is a basic property, which is usually required as far as the circuitry is concerned. The experiments were conducted to confirm a LED device of the present invention has a satisfactory solder leach resistant. Specifically, four samples that have satisfactory solder leach resistant were compared with a sample of the present invention.

(Sample 1)

A silver paste as a thick film paste was screen-printed to the surface of DLC sheet, thereby forming a prescribed conductive pattern. The paste was dried at 150° C. for 10 minutes, and then cured at 200° C. for 30 minutes. The sample was subsequently gold plated for the purpose of wirebonding. The composition of the silver paste and the conductive pattern are shown in Table 1.

TABLE 1

| Paste | Screen/Pattern |
|---|---|
| Platable Polymer | PH-0 |
| Silver Paste | Mesh Count 325 |
| Glass-free | Emulsion 15 μm |
| Viscosity: 40.6 Pa · s @ 10 rpm, | Stainless Steel |
| 365 Pa · s @ 0.5 rpm | |

(Control Sample 2-5)

Four existing samples (QS174, 5164N, 6179A, 6177T), was prepared by screen-printing a thick film paste to alumina plate as a reference.

Sample 1 and control sample 2-5 were dipped in 63 Sn/37 Pb liquid for 5 second. This dipping was repeated until solder leach took place.

To determine solder leach resistance, the electrical resistance of the serpentine-shaped pattern was measured. A point of failure at which solder leach occurs was identified when it was short-circuited.

TABLE 2

| | Numbers of |
|---|---|
| | Dipping until Failure |
| | occurred |
| Control Sample 1 | 4 |
| Control Sample 2 | 4 |
| Control Sample 3 | 6 |
| Control Sample 4 | 8 |
| Sample 1 | 10 |

As shown in Table 2, the present invention shows better solder leach resistant than conventional combinations.

2. Reliability Test

Samples with circuit build on the DLC-coated substrates will be tested to verify the reliability of the circuitry materials. We anticipate that reliability testing will show superior performance as compared to prior art.

Typical reliability items includes:

(1) Temperature Conditions

(2) Humidity Conditions

(3) Corrosion test

Samples of LED packaged on the claimed circuitry/Substrate will be subjected to reliability tests as well. Additional testing items might include:

(1) Longevity Characteristics

(2) Electrical Current Conditions

(3) Mechanical shock conditions

3. Heat Management Performance Test

Samples are tested in such a way that heat management performance of the LED devices using structures claimed in this invention will be compared with those of other commercially available substrates and packaging structure.

We anticipate that the present invention will show superior heat management performance, including excellent heat conductivity properties, resulting in better device (LED device or end use) quality (i.e., longer life, efficiency of emittance, etc.) as compared with other commercially available substrates and packaging structures.

1. A LED device, comprising:
a substrate;
a diamond-like carbon layer disposed on the substrate;
an electric circuit formed on the diamond-like carbon layer; and
a LED chip electrically connected to the electric circuit, wherein the substrate is a aluminum plate or aluminum alloy plate and an anodized layer is formed between the substrate and the diamond-like carbon layer.

2. (canceled)

3. (canceled)

4. A LED device according to claim 1, wherein the LED chip is wirebonded to the electric circuit.

5. A LED device according to claim 1, wherein the LED chip is flip-chip bonded on the surface of the electric circuit.

6. A LED device according to claim 1, wherein the LED chip is mounted on the diamond-like carbon layer.

7. A back panel of liquid crystal display, wherein LED devices of claim 1 are used as a source of light.

8. A method of forming a LED device comprising:
providing a substrate;
providing a diamond-like carbon layer disposed on the substrate;
forming an electric circuit formed on the diamond-like carbon layer; and electrically connecting a LED chip to the electric circuit, wherein the substrate is a aluminum plate or aluminum alloy plate and an anodized layer is formed between the substrate and the diamond-like carbon layer.
